(19) United States
(12) Patent Application Publication
(10) Pub. No.: US 2006/0139070 A1
(43) Pub. Date: Jun. 29, 2006

(54) Initialization circuit for a semiconductor

(75) Inventor: Keun Kook Kim, Cheongju (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/174,692

(22) Filed: Jul. 5, 2005

(30) Foreign Application Priority Data
Dec. 28, 2004 (KR) 2004-114422

(51) Int. Cl. H03L 7/00

(52) U.S. Cl. 327/143

(57) ABSTRACT

An initialization circuit for a semiconductor device is disclosed. The initialization circuit comprises an internal voltage detector for outputting a desired level of voltage signal in response to a level of an internal voltage, a voltage corrector for correcting a voltage at an output terminal of the intemal voltage detector to a desired voltage level until the level of the intenal voltage reaches a reference voltage level for an initialization operation of the semiconductor device, and a buffer for buffering the output signal of the internal voltage detector, corrected by the voltage corrector, to output an enable signal for initialization of the semiconductor device.

### BACKGROUND OF THE INVENTION

1. Field of the Invention

The present invention relates to an initialization circuit for a semiconductor device, and more particularly to an initialization circuit for a semiconductor device which is capable of detecting the level of internal voltage and outputting an enable signal for initialization of the semiconductor device after the level of the internal voltage is stabilized.

2. Description of the Related Art

In general terms, an initialization circuit in a semiconductor device means a circuit that takes charge of the initialization of a semiconductor chip. The fundamental object of this initialization circuit is to initialize all internal circuits of the semiconductor device after power supply voltages, such as an internal power supply voltage, an external power supply voltage, and the like, are stabilized, such that the semiconductor device operates in a stable manner. In this connection, it is necessary to guarantee the initialization of the semiconductor device for the smooth operation thereof To this end, the initialization circuit is adapted to detect the level of the internal power supply voltage and generate an enable signal for the initialization of the semiconductor device after the level of the internal power supply voltage is stabilized to a predetermined reference level.

However, such a conventional initialization circuit has a disadvantage in that it generates the enable signal for the initialization of the semiconductor device even before the level of the internal power supply voltage is stabilized to the predetermined reference level, resulting in a faulty operation of the semiconductor device.

The above problem with the conventional initialiazation circuit for the semiconductor device will hereinafter be described in detail with reference to the annexed drawings.

FIG. 1 shows the configuration of the conventional initialization circuit for the semiconductor device. In FIG. 1, the reference numeral 100 denotes an internal voltage detector which acts to detect the level of an internal voltage, and 110 denotes a buffer which acts to buffer an output signal from the internal voltage detector.

A description will hereinafter be given of the basic operation of the initialization circuit with reference to FIG. 1. First, in an initial state where an intemal voltage VINT is low in level, a node A becomes low in level because an NMOS transistor N11 is turned on. Then, a node B becomes high in level and a node C becomes low in level. As a result, a PMOS transistor P16 in the buffer 10 is turned on, thereby causing a node D to become high in level. This high level signal from the node D is applied to the gate of an NMOS transistor N15 to turn the NMOS transistor N15 on, so as to make the voltage of an output terminal OUT lower. Accordingly, in the initial state where the internal voltage VINT level is low, an initialization operation is not performed yet since the voltage signal of the output terminal OUT, which is an initialization enable signal, is low in level.

On the other hand, when the internal voltage VINT rises from a low level and is then stabilized to a predetermined reference voltage or more, the node A makes a low to high level transition. Then, node B becomes lower in level and node C becomes higher in level. As a result, an NMOS transistor N14 in the buffer 110 is turned on, thereby causing node D to go from a high to low level. This low level signal from node D is applied to the gate of a PMOS transistor P17 to turn the PMOS transistor P17 on, so as to make the level of voltage of the output terminal OUT higher. Thus, when the internal voltage VINT rises and is stabilized to a predetermined reference voltage or more, the initialization enable signal, or the voltage signal of the output terminal OUT, becomes higher, so that the semiconductor device performs the initialization operation.

However, the initialization circuit for the semiconductor device has the disadvantage in that, differently from the aforementioned basic operation, generating the initialization enable signal even before the internal voltage is stabilized to a predetermined reference voltage level or more, thereby causing the semiconductor device to perform a faulty initialization operation, as will hereinafter be described in detail.

In the initial state where the internal voltage VINT is low in level, PMOS transistors P14 and P15 cannot normally perform inverting operations because they are applied with a low level internal voltage VINT.

Accordingly, in the initial state, even if node A is low in level, node B cannot assume a constantly high level, so a low level period is present at node B. As a result, node C also cannot be continuously maintained at a low level, resulting in the presence of a high level period at node C. Consequently, the initialization enable signal OUT at the output terminal OUT also becomes higher in level as a result of inverting operations of inverters 111 and 112, thereby causing the semiconductor device to perform the initialization operation even before the internal voltage VINT is stabilized to a predetermined reference voltage level or higher.

FIG. 2 shows the waveforms of voltages at respective nodes in the conventional initialization circuit for the semiconductor device to explain the operation of the conventional initialization circuit. In the initial state where the internal voltage VINT level is low, node B does not assume a constant high level, so node C is also not maintained at a low level and thus rises to a set voltage or more, for example, about 700 mV, so as to become higher in level. As a result, as can be seen from FIG. 2, in the initialization enable signal OUT, a faulty operation period is present in which the enable signal OUT becomes higher in the above period.

### SUMMARY OF THE INVENTION

Therefore, the present invention has been made in view of the above problems, and it is an object of the present invention to provide an initialization circuit for a semiconductor device wherein the period in which an initilization enable signal is enabled is not generated before the internal voltage of the semiconductor device rises and is stabilized at a predetermined reference voltage level or higher, so that the semiconductor device can perform an initialization operation only after the internal voltage is stabilized.

In accordance with the present invention, the above and other objects can be accomplished by the provision of an initialization circuit for a semiconductor device, comprising: an internal voltage detector for outputting a desired level of voltage signal in response to the level of an internal voltage; a voltage corrector for correcting the voltage at an output terminal of the internal voltage detector to a desired voltage level until the level of the internal voltage reaches a reference voltage level for an initialization operation of the semiconductor device; and a buffer for buffering the output signal of the internal voltage detector, corrected by the voltage corrector, to output an enable signal for initialization of the semiconductor device.

Preferably, the voltage corrector maintains the output terminal of the internal voltage detector at a low level until the level of the internal voltage reaches the reference voltage level. To this end, the voltage corrector may include an NMOS transistor for maintaining the output terminal of the internal voltage detector at the low level in response to an external voltage. The NMOS transistor may be of a long channel type. Preferably, the internal voltage detector includes an even number of inverting buffers.

As an alternative, the voltage corrector may maintain the output termial of the internal voltage detector at a high level until the level of the internal voltage reaches the reference voltage level. To this end, the voltage corrector may include a PMOS transistor for maintaining the output terminal of the internal voltage detector at a high level in response to a ground voltage. The PMOS transistor may be of a long channel type. Preferably, the internal voltage detector includes an odd number of inverting buffers.

Preferably, the buffer includes at least one inverter.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a circuit diagram showing the configuration of a conventional initialization circuit for a semiconductor device;

FIG. 2 is a waveform diagram showing the waveforms of voltages at respective nodes in the conventional initialization circuit for the semiconductor device to explain the operation of the conventional initialization circuit;

FIG. 3 is a circuit diagram showing the configuration of an initialization circuit for a semiconductor device according to a first embodiment of the present invention;

FIG. 4 is a circuit diagram showing the configuration of an initialization circuit for a semiconductor device according to a second embodiment of the present invention; and

FIG. 5 is a waveform diagram showing the waveforms of voltages at respective nodes in the initialization circuit for the semiconductor device according to the first embodiment of the present invention to explain the operation of the initialization circuit.

### DESCRIPTION OF THE PREFERRED EMBODIMENTS

Now, preferred embodiments of the present invention will be described in detail with reference to the annexed drawings. It should be noted herein that these embodiments are only for illustrative purposes and the protection scope of the invention is not limited thereto.

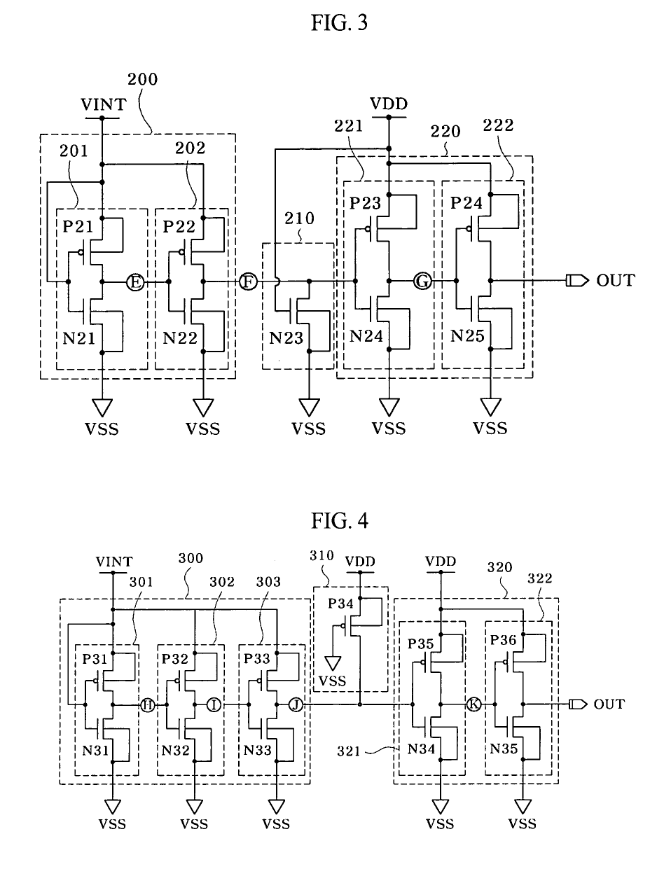

FIG. 3 is a circuit diagram showing the configuration of an initialization circuit for a semiconductor device according to a first embodiment of the present invention.

As shown in FIG. 3, the initialization circuit for the semiconductor device according to the first embodiment comprises an internal voltage detector 200 for outputting a desired level of a voltage signal in response to the level of internal voltage VINT, a voltage corrector 210 for correcting a voltage at an output terminal F of the internal voltage detector 200 to maintain the output terminal F at a desired voltage level, preferably a low level, until the level of the internal voltage VINT reaches a referenced voltage level for an initialization operation of the semiconductor device, and a buffer 220 for buffering the output signal F of the internal voltage detector 200, corrected by the voltage corrector 210, to output an enable signal OUT for initialization of the semiconductor device.

Here, the voltage corrector 210 includes an NMOS transistor N23 for maintaining the output terminal F of the internal voltage detector 200 at the low level in response to an external voltage VDD. The internal voltage detector 200 includes an even number of inverters 201 and 202. The buffer 220 includes one or more inverters 221 and 222.

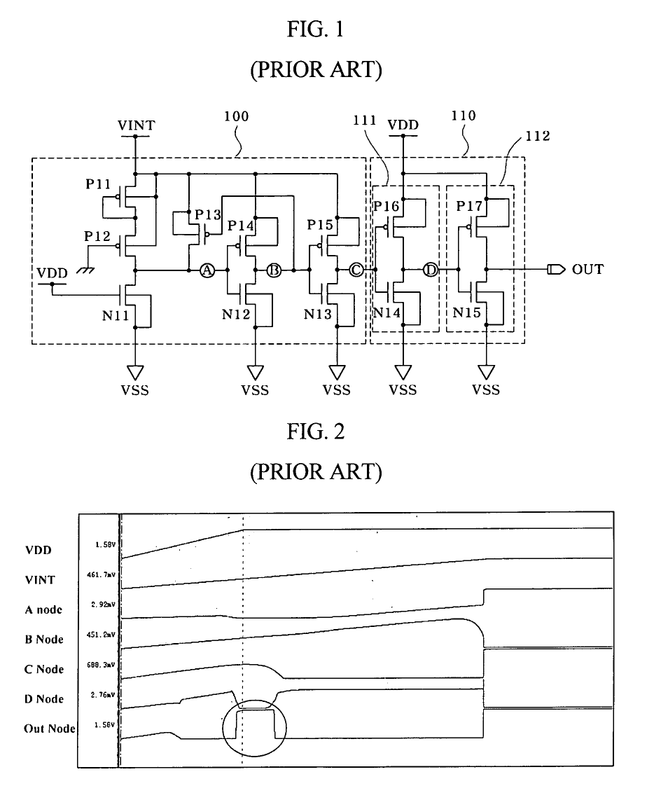

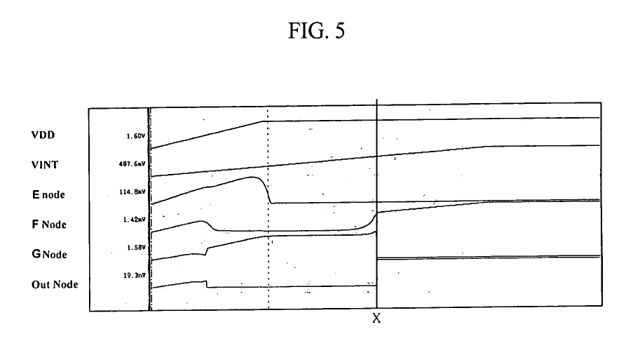

The operation of the initialization circuit with the above-stated configuration according to the first embodiment will hereinafter be described in detail with reference to FIG. 1 and FIG. 5 which shows the waveforms of the voltages at respective nodes in the initialization circuit.

In the initial state, both the external voltage VDD and internal voltage VINT of the semiconductor device gradually rise from low levels as shown in FIG. 5. First, in the initial state, the low level internal voltage VINT is inputted to the inverter 201. At this time, however, the inverter 201 cannot normally perform an inverting operation because it also receives the low level internal voltage VINT as a source voltage. As a result, even though the voltage inputted to the inverter 201 is low in level, the voltage level of node E is not fixed at a low or high level, but floats as shown in FIG. 5. Similarly, since the inverter 202 also receives the internal voltage VINT as a source voltage, it cannot normally perform an inverting operation, thereby causing the voltage level of node F to float, also.

However, in this first embodiment, the voltage corrector 210 is installed to correct the voltage level of the node F to maintain it at a low level. That is, as shown in FIG. 5, the external voltage VDD rises at a steeper slope than the internal voltage VINT, so that it reaches the vicinity of a high level of a certain voltage or earlier than the intenal voltage VINT in spite of the condition that the internal voltage VINT is not yet stabilized. As a result, the NMOS transistor N23 in the voltage corrector 210 which receives this external voltage VDD at its gate is turned on to pull node F down so as to maintain the voltage level of node F at the low level. It can be seen from FIG. 5 that, in the present embodiment, the voltage level of node F rises to a maximum of 200 mV and is then maintained constant at a low level by the operation of the voltage corrector 210. Here, the NMOS transistor N23 is an MOS transistor of a long channel type and is designed to act to pull node F down to a low level with little current consumption.

With the voltage level of node F maintained at a low level in the above manner, node G, or an output terminal of the inverter 221, becomes high in level and an output terminal OUT of the inverter 222 becomes low in level. Consequently, the initialization enable signal OUT at the output terminal OUT becomes low in level, so that the semiconductor device of the present embodiment, designed such that the initialization operation is disabled when the initialization enable signal OUT is low in level and enable when the initialization enable signal OUT is high in level, cannot perform the initialization operation in the initial state where the internal voltage VINT is low in level. This state is maintained until the internal voltage VINT reaches the reference voltage level for the initialization operation of the semiconductor device (i.e., until a time X), as shown in FIG. 5. The reference voltage level may be determined differently depending on installation environments, system environment, operation conditions, and the like of the semiconductor device.

Meanwhile, when the internal voltage VINT rises to the reference voltage level or more and thus becomes high in level, the inverter 201 and inverter 202 included in the internal voltage detector 200 can normally perform the inverting operations. Accordingly, node E goes to a lower level by the inverting operation of the inverter 201 and node F goes to a higher level by the inverting operation of the inverter 202. In the present embodiment, the voltage driving capability of a PMOS transistor P22 to drive node F to a high level is designed to be larger than the voltage driving capability of the NMOS transistor N23 of the long channel type in the voltage corrector 210 to drive node F to a low level, when the internal voltage VINT is the reference voltage level or more. Thus, in the present embodiment, when the internal voltage VINT becomes higher than or equal to the reference voltage level, the voltage level of node F makes the transition from a low to a high level.

When the voltage level of node F goes from a low to high level as described above, the node G, or the output terminal of the inverter 221, becomes low in level and the output terminal OUT of the inverter 222 becomes high in level. In conclusion, at the time the internal voltage VINT is stabilized to the reference voltage level or more, the initialization circuit according to this embodiment outputs the initialization enable signal OUT of the high level through the output terminal OUT so that the semiconductor device can perform the initialization operation.

In brief, the initialization circuit for the semiconductor device according to the first embodiment maintains the output terminal F of the internal voltage detector 200 at a low level through the operation of the voltage corrector 210 in the initial state where the internal voltage VINT is lower than the reference voltage level. Therefore, the initialization enable signal OUT from the buffer 220 is disabled such that a faulty initialization operation is not performed. At the time that the internal voltage VINT is stabilized to the reference voltage level or more, the initialization circuit changes the output terminal F of the internal voltage detector 200 to a high level to enable the initialization enable signal OUT from the buffer 220 so that the initialization operation can be normally performed.

Although the internal voltage detector 200 has been disclosed in the present embodiment to include two inverters, it may include any even number of inverters depending on system environments and operation conditions of the semiconductor device.

FIG. 4 is a circuit diagram showing the configuration of an initialization circuit for a semiconductor device according to a second embodiment of the present invention

As shown in FIG. 4, the initialization circuit for the semiconductor device according to the second embodiment comprises an internal voltage detector 300 for outputting a desired level of voltage signal in response to the level of an internal voltage VINT, a voltage corrector 310 for correcting the voltage at an output terminal J of the internal voltage detector 300 to maintain the output terminal J at a desired voltage level, preferably a high level, until the level of the internal voltage VINT reaches a reference voltage level for an initialization operation of the semiconductor device, and a buffer 320 for buffering the output signal J of the internal voltage detector 300, corrected by the voltage corrector 310, to output an enable signal OUT for initialization of the semiconductor device.

Here, the voltage corrector 310 includes a PMOS transistor P34 for maintaining the output terminal J of the internal voltage detector 300 at the high level in response to a ground voltage VSS. The internal voltage detector 300 includes an odd number of inverters 301, 302 and 303. The buffer 320 includes one or more inverters 321 and 322.

The operation of the initialization circuit with the above-stated configuration according to the second embodiment will hereinafter be described in detail with reference to FIG. 4.

In the initial state, both the external voltage VDD and internal voltage VINT of the semiconductor device gradually rise from low levels. First, in the initial state, the low level internal voltage VINT is inputted to the inverter 301. In this case, however, the inverter 301 cannot normally perform an inverting operation because it also receives the low level internal voltage VINT as a source voltage. Thus, even though the voltage inputted to the inverter 301 is low in level, the voltage level of a node H is not fixed at a low or high level, but floats. Similarly, since the inverter 302 and inverter 303 also receive the low level internal voltage VINT as a source voltage, they cannot normally perform inverting operations, thereby causing the voltage levels of node I and node J to float, also.

However, in this second embodiment, the voltage corrector 310 is installed to correct the voltage level of the node J to maintain it at a high level. That is, as shown in FIG. 5, the external voltage VDD rises at a steeper slope than the internal voltage VINT, so that it reaches in the vicinity of a high level of a certain voltage or more earlier than the internal voltage VINT in spite of the condition that the unstable internal voltage VINT. As a result, the PMOS transistor P34 in the voltage corrector 310 which receives the ground voltage VSS at its gate and the external voltage VDD at its source is turned on to pull node J up so as to maintain the voltage level of node J at a high level. Here, the PMOS transistor P34 is a MOS transistor of a long channel type and is designed to act to pull node J up to the high level with little current consumption.

With the voltage level of node J maintained at the high level in the above manner, node K, or an output terminal of the inverter 321, becomes low in level and the output terminal OUT of the inverter 322 becomes higher in level. As a result, the initialization enable signal OUT at the output terminal OUT becomes high in level, so that the semiconductor device of the present embodiment, designed such that the initialization operation is disabled when the initialization enable signal OUT is high in level and enabled when the initialization enable signal OUT is low in level, cannot perform the initialization operation in the initial state where the internal voltage VINT is high in level. This state is maintained until the internal voltage VINT reaches the reference voltage level for the initialization operation of the semiconductor device. The reference voltage level may be determined differently depending on installation environment, system environments, operation conditions, or the like of the semiconductor device.

On the other hand, when the internal voltage VINT rises to the reference voltage level or more and thus becomes high in level, the inverter 301, inverter 302 and inverter 303 included in the internal voltage detector 300 can normally perform the inverting operations. Hence, the node H lowers in level by the inverting operation of the inverter 301, node I goes high in level by the inverting operation of the inverter 302, and node J lowers in level by the inverting operation of the inverter 303. In the present embodiment, the voltage driving capability of an NMOS transistor N33 to drive node J to a low level is designed to be larger than the voltage driving capability of the PMOS transistor P34 of the long channel type in the voltage corrector 310 to drive node J to a high level, when the internal voltage VINT is the reference voltage level or more. Thus, in the present embodiment, when the internal voltage VINT becomes higher than or equal to the reference voltage level, the voltage level of node J moves from a high to a low level transition.

When the voltage level of node J goes from a high to low in level as described above, node K, or the output terminal of the inverter 321, becomes high in level and the output terminal OUT of the inverter 322 becomes low in level. In conclusion, at the time that the internal voltage VINT is stabilized to the reference voltage level or more, the initialization circuit according to this embodiment outputs the initialization enable signal OUT of the low level through the output terminal OUT so that the semiconductor device can perform the initialization operation.

Summarizing the above-described contents, the initialization circuit for the semiconductor device according to the second embodiment maintains the output terminal J of the internal voltage detector 300 at a high level through the operation of the voltage corrector 310 in the initial state where the internal voltage VINT is lower than the reference voltage level. Therefore, the initialization enable signal OUT from the buffer 320 is disabled such that a faulty initialization operation is not performed. At the time that the internal voltage VINT is stabilized to the reference voltage level or more, the initialization circuit changes the output termial J of the internal voltage detector 300 to a low level to enable the initialization enable signal OUT from the buffer 320 so that the initialization operation can be normally performed.

Although the internal voltage detector 300 has been disclosed in the present embodiment as including three inverters, it may include any odd number of inverters depending on system environments and operation conditions of the semiconductor device.

As apparent from the above description, the present invention provides an initialization circuit for a semiconductor device wherein, until an internal voltage of the semiconductor device is stabilized to a predetermined reference voltage level or more, a voltage at an output terminal of an internal voltage detector is continuously maintained at a high or low level such that an initialization enable signal is not enabled, thereby preventing the semiconductor device from performing a faulty initialization operation, thus securing product stability.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An initialization circuit for a semiconductor device, comprising:
an internal voltage detector for outputting a desired level of voltage signal in response to the level of an internal voltage;
a voltage corrector for correcting a voltage at an output terminal of the internal voltage detector to a desired voltage level until the level of the internal voltage reaches a reference voltage level for an initialization operation of the semiconductor device; and
a buffer for buffering the output signal of the internal voltage detector, corrected by the voltage corrector, to output an enable signal for initialization of the semiconductor device.

2. The initialization circuit as set forth in claim 1, wherein the voltage corrector is adapted to maintain the output terminal of the internal voltage detector at a low level until the level of the internal voltage reaches the reference voltage level.

3. The initialization circuit as set forth in claim 2, wherein the voltage corrector includes an NMOS transistor for maintaining the output terminal of the internal voltage detector at the low level in response to an external voltage.

4. The initialization circuit as set forth in claim 3, wherein the NMOS transistor is of a long channel type.

5. The initialization circuit as set forth in claim 2, wherein the internal voltage detector includes an even number of inverting buffers.

6. The initialization circuit as set forth in claim 1, wherein the voltage corrector is adapted to maintain the output terminal of the intemal voltage detector at a high level until the level of the internal voltage reaches the reference voltage level.

7. The initialization circuit as set forth in claim 6, wherein the voltage corrector includes a PMOS transistor for maintaining the output terminal of the internal voltage detector at the high level in response to a ground voltage.

8. The initialization circuit as set forth in claim 7, wherein the PMOS transistor is of a long channel type.

9. The initialization circuit as set forth in claim 6, wherein the internal voltage detector includes an odd number of inverting buffers.

10. The initialization circuit as set forth in claim 1, wherein the buffer includes at least one inverter.
